(19) United States
(12) Patent Application Publication
(10) Pub. No.: US 2006/0094267 A1
(43) Pub. Date: May 4, 2006

(54) Plug

(76) Inventor: Guoli Li, Shanghai (CN)

Correspondence Address: MOLEX INCORPORATED, 2222 WELLINGTON COURT, LISLE, IL, 60532, US

(21) Appl. No.: 11/264,637

(22) Filed: Nov. 1, 2005

(30) Foreign Application Priority Data
Nov. 1, 2004 (CN) 200420117687.9

(51) Int. Cl. H05K 1/00

(52) U.S. Cl. 439/76.1

(57) ABSTRACT

The present invention discloses a plug, which matches a corresponding socket. The plug comprises a body, a shell, a plurality of terminals and a plurality of wires. The body has a first contact surface directing to the corresponding socket, a second contact surface corresponding to the first contact surface and a plurality of terminal channels formed between the first contact surface and the second contact surface. Each terminal has a connection end that extends from the second contact surface out of the terminal channel and is accepted by the shell. On one side of the shell, the wires connect to the shell and the connection direction is vertical to the first contact surface. A gold finger board, placed in the shell, has a plurality of leads, each lead having a soldering pad connecting to the corresponding terminal at one end and having a gold finger connecting to the corresponding wire at another end. The plug of present invention provides the advantages of avoiding twisting of the wire and saving space.

### FIELD OF THE INVENTION

The present invention relates to a plug, more particularly to a plug wherein the wires of a cable connected to the plug is capable of being connected from a side of the plug shell.

### BACKGROUND OF THE INVENTION

Since the 1980s, the ATA (Advanced Technology Attachment) interface has been the desktop computer standard for memory storage equipment interconnection. However, with the improved computer operation speeds, the data amount involved is increasing constantly, and the relatively unsophisticated parallel ATA interface is beginning to show its limitations. Therefore, the SATA standard naturally plays an upgrading role. For users, equipment using SATA device(s) will provide the advantages of faster data transmission, high reliability and easier operation.

FIG. 1 is a perspective view of a conventional SATA plug 8. The SATA plug 8 comprises a body 80, a shell 81, a plurality of terminals 82 and a plurality of wires 83 connected to the terminals 82. The top cover of the shell 81 is removed to show more clearly the detailed structure inside the shell 81. The body 80, appearing as an approximately rectangular body, comprises a first contact surface (not shown) directing to a corresponding socket (not shown) and a second contact surface 800 corresponding to the first contact surface. A plurality of terminal channels (not shown) penetrates from the first contact surface to the second contact surface 800. A major portion of each terminal 82 is received by the corresponding terminal channel. The shell 81 extends from the second contact surface 800 of the body 80. A connection end 820 of the terminal 82 also extends from the second contact surface 800 into the shell 81. The wire 83, plugging into the shell 81 on a second side 811 corresponding to a first side 810, connects to the corresponding terminal 82 in the shell 81 according to the SATA standard.

As shown in FIG. 2, the connection directions of plugs at the devices 9, 9′ in a computer system are not aligned; that is, they are perpendicular to each other. The wires 83 of the conventional SATA plug 8 need twisting somewhat for connection. In the situations of more devices 9, 9′ in a computer system or compact assembling space, the twisted wires will cause a state of chaos and even interference. Therefore, the matter of connection of the conventional SATA plug 8 needs further improvement.

### SUMMARY OF THE INVENTION

The objective of the present invention is to provide a plug that lessens twist and winding of the wires during connection and then keeps the assembling space neat and tidy. In order to achieve the objective, a plug is disclosed, which matches a corresponding socket. The plug comprises a body, a shell, a plurality of terminals and a plurality of wires. The body contains a first contact surface directing to the corresponding socket, a second contact surface corresponding to the first contact surface and a plurality of terminal channels penetrating from the first contact surface to the second contact surface. The terminal has a connection end that extends from the second contact surface out of the terminal channel and is received by the shell. The wires are connected to the shell on a side thereof and the connection direction is perpendicular to the first contact surface.

The terminal and the wire are connected directly in the shell or are connected through a circuit board in the shell. A gold finger board, which may be selected as the circuit board, has a plurality of leads. The leads have a soldering pad at one end, connecting to the corresponding terminal and a gold finger at another end, connecting to the corresponding wire.

### BRIEF DESCRIPTION OF THE DRAWINGS

The organization and manner of the structure and operation of the invention, together with further objects and advantages thereof, may best be understood by reference to the following description taken in connection with the accompanying drawings wherein like reference numerals identify like elements in which:

FIG. 1 shows a perspective view of a conventional SATA plug with the top cover of the shell removed;

FIG. 2 illustrates the devices using the conventional SATA plugs;

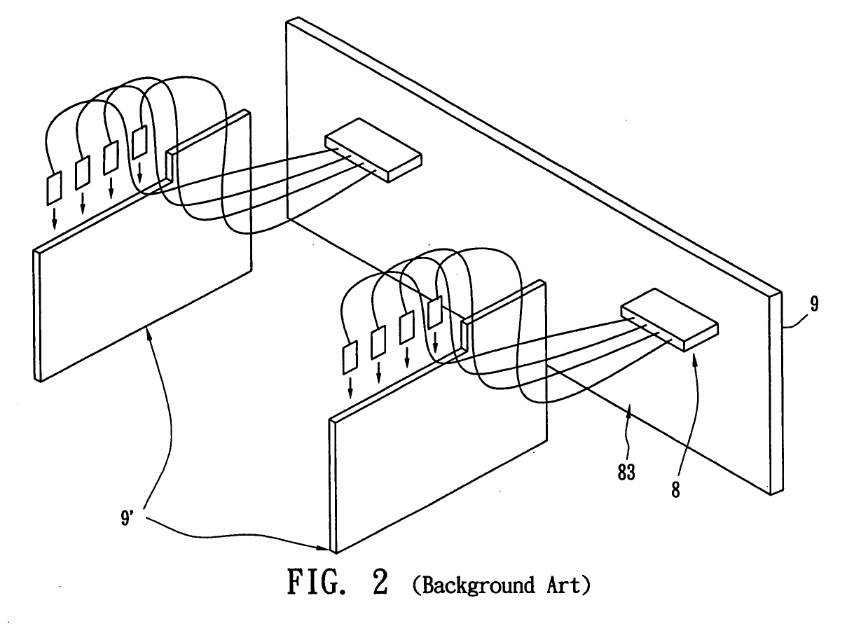

FIG. 3 illustrates a plug of one embodiment of the present invention with top cover of the shell removed;

FIG. 4 is a top plan view of the plug of FIG. 3; and

FIG. 5 shows a perspective view of the opposite side of the plug of FIG. 3 with the bottom cover of the shell removed and a corresponding socket.

### DETAILED DESCRIPTION OF THE DISCLOSED EMBODIMENT

While this invention may be susceptible to embodiment in different forms, there is shown in the drawings and will be described herein in detail, a specific embodiment with the understanding that the present disclosure is to be considered an exemplification of the principles of the invention, and is not intended to limit the invention to that as illustrated.

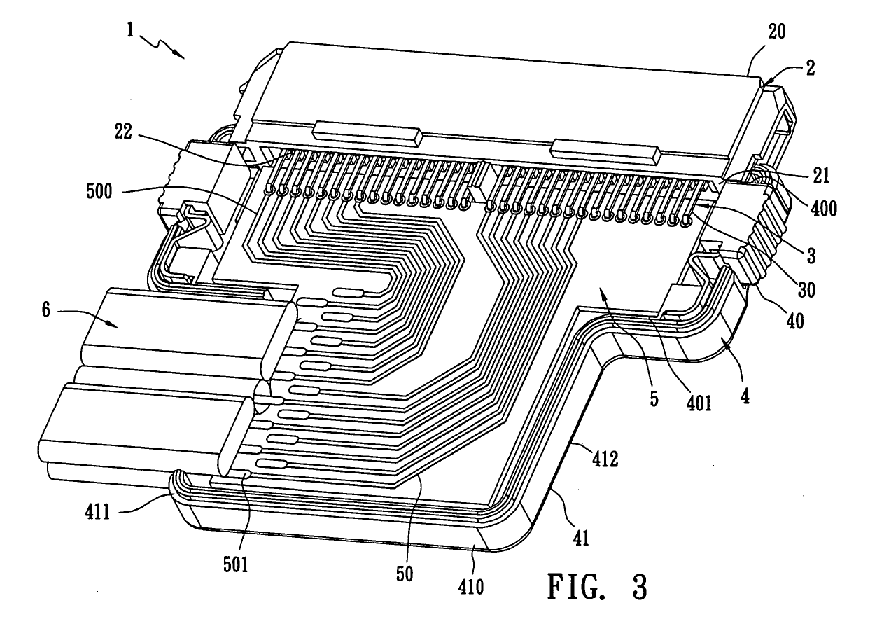

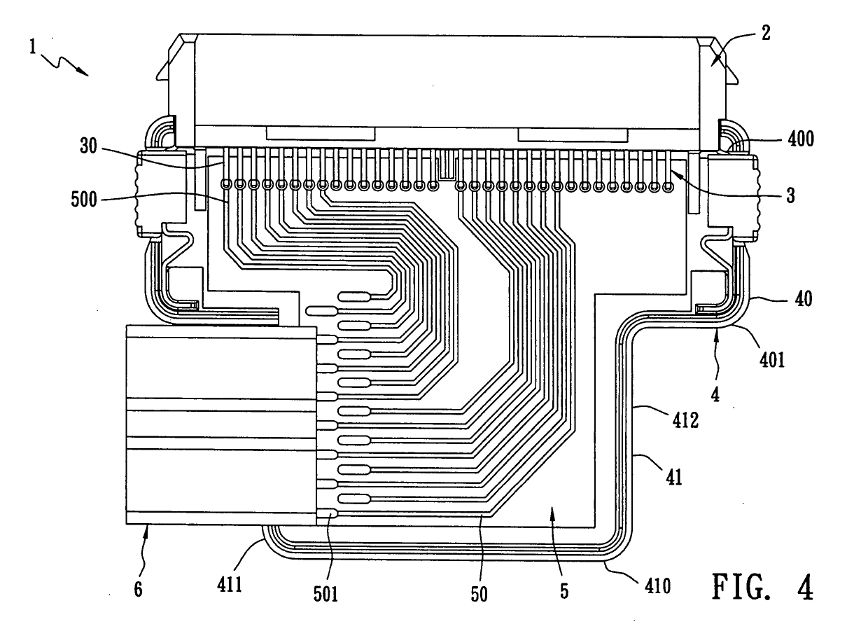

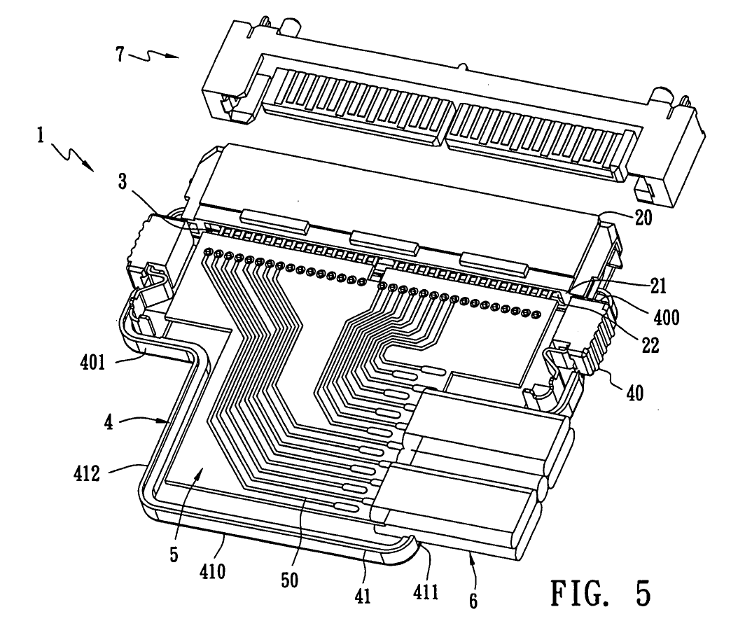

Referring to FIGS. 3-5 simultaneously, the plug 1, according to a preferred embodiment of the present invention, can match a corresponding socket 7. The plug 1 comprises a body 2, a plurality of terminals 3, a shell 4, a gold finger board 5 and a plurality of wires 6. The body 2, approximately rectangular, contains a first contact surface 20 directing to the socket 7, a second contact surface 21 corresponding the first contact surface 20 and a plurality of terminal channels 22 penetrating from the first contact surface 20 to the second contact surface 21.

Each terminal 3 has a plug end (not shown) directing to the socket 7 and a connection end 30 extending from the plug end. The plug end is accommodated by the terminal channel 22 located in the body 2. The connection end 30 extends from the second contact surface 21 out of the terminal channel 22 and is received by the shell 4.

In the preferred embodiment, the shell 4 appears approximately as a T-shape. The transverse portion 40 of the T-shape, extending from the second contact surface 21 of the body 2, has a first end surface 400 contacting the second contact surface 21 and a second end surface 401 corresponding to the first end surface 400. The lengthwise portion 41 of the T-shape, extending approximately from the middle of the second end surface 401, has a free end surface 410 corresponding to the second end surface 401. The second end surface 401 and the free end surface 410 are connected by a second side surface 412 of the lengthwise portion 41. A first side surface 411, connecting to the free end surface 410, corresponds to the second side surface 412. The wires 6 are connected to the shell 4 on a side thereof (i.e., the first side surface 411 or the second side surface 412). In the preferred embodiment, the shape of the shell 4 appearing as a T-shape is for the sake of space concerns. However, other shapes like a rectangular solid are applicable as long as the connection direction of the wires 6 into the shell 4 is perpendicular to the first contact surface 20 of the body 2.

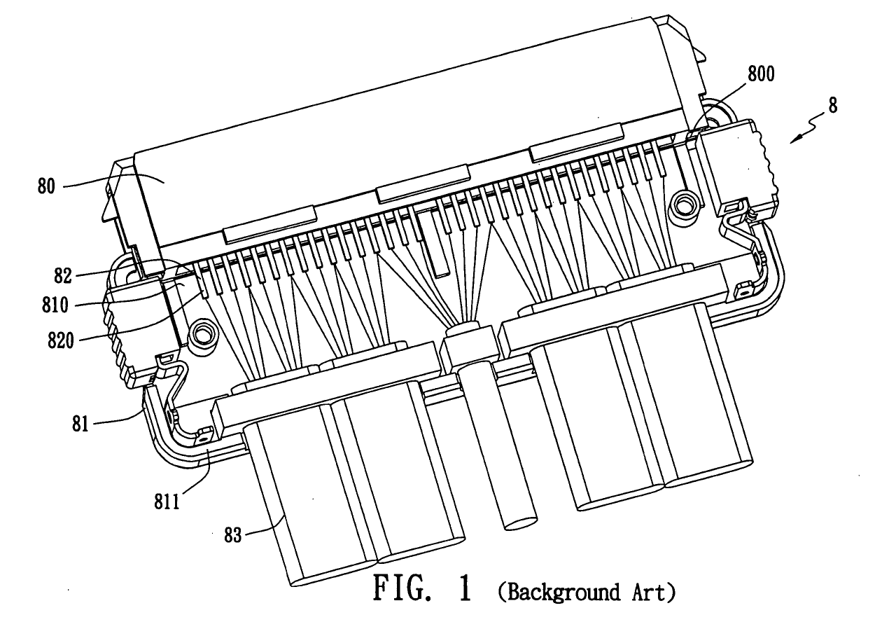

In addition, the shape of the gold finger board 5 corresponds to that of the shell 4 to be firmly accepted in the shell 4. A plurality of leads 50 is located on the gold finger board 5. An end 500 of the lead 50, extending through the first side surface 400 of the shell 4, is welded to the corresponding terminal 3 on a soldering pad; another end 501 of the lead 50, extending close to the first side surface 411 through which the wires 6 come to the shell 4, connects to the corresponding wire 6 by a gold finger 52. The connection between the wires 6 and the gold fingers 52 complies with the connection standard followed by current similar plugs. In the preferred embodiment, the SATA standard, referring to FIG. 1, is used and its details are omitted.

In practical operation, the gold finger board 5 could be omitted to make the wires 6 directly and electrically connected to the connection end 30 of the terminal 3 to reduce noise interference.

The plug of the present invention allows the connection direction of the wires to be perpendicular to the second contact surface that matches the corresponding socket. As a result, the issue of wire twisting and winding is eliminated and less assembling space is occupied.

While a preferred embodiment of the invention is shown and described, it is envisioned that those skilled in the art may devise various modifications without departing from the spirit and scope of the foregoing description and the appended claims.

What is claimed is:

1. A plug connector, comprising:
a body having:
a first contact surface;
a second contact surface; and
a plurality of terminal channels penetrating from the first contact surface to the second contact surface;
a shell;
a plurality of terminals, each terminal having a connection end that extends from the second contact surface out of the terminal channel and is received in the shell, wherein the terminals are capable of being connected to a plurality of wires from a side of the shell, the connection direction between the wires and the terminals is generally perpendicular to the first contact surface.

2. The plug of claim 1, wherein the connection ends are directly and electrically connected to the wires in the shell.

3. The plug of claim 1, wherein the terminals are electrically connected to the wires through a circuit board located in the shell.

4. The plug of claim 3, wherein the circuit board is a gold finger board having a plurality of leads thereon, each lead having a soldering pad connected to the corresponding terminal at one end and having a gold finger connected to the corresponding wire at another end.
